(19) United States
(12) Patent Application Publication
(10) Pub. No.: US 2024/0410928 A1
(43) Pub. Date: Dec. 12, 2024

(54) FAULT LOCATION IN ACTIVE COMPENSATION RESONANT GROUNDED POWER DISTRIBUTION SYSTEM

(71) Applicant: Sentient Energy Technology, LLC, Wichita, KS (US)

(72) Inventors: Timothy Robert Figura, Walnutport, PA (US); Kartikeya Tripathi, Clarksburg, MD (US)

(21) Appl. No.: 18/737,699

(22) Filed: Jun. 7, 2024

Related U.S. Application Data
(60) Provisional application No. 63/471,503, filed on Jun. 7, 2023.

(51) Int. Cl. G01R 31/08; H02H 3/16

(52) U.S. Cl. CPC G01R 31/086; G01R 31/088; H02H 3/165

(57) ABSTRACT

Disclosed are various embodiments for fault location in an active compensation resonant grounded power distribution system. In one embodiment, an inverter is programmed to allow a configurable set of triplen harmonics to pass during the ground fault condition for a duration of time. First current sensor data from a first line sensor mounted on a line conductor is analyzed to determine that a programmable set of harmonic currents are present. Second current sensor data from a second line sensor mounted on the line conductor is analyzed to determine that the programmable set of harmonic currents are absent. The second line sensor is downstream of the first line sensor on the line conductor. A ground fault being compensated for by the active compensation resonant grounded power distribution system is determined to be present on the line conductor between the first line sensor and the second line sensor.

### CROSS-REFERENCE TO RELATED APPLICATIONS

This application claims priority to, and the benefit of, U.S. Provisional Patent Application No. 63/471,503, entitled “FAULT LOCATION IN ACTIVE COMPENSATION RESONANT GROUNDED POWER DISTRIBUTION SYSTEM,” and filed on Jun. 7, 2023, which is incorporated herein by reference in its entirety.

### BACKGROUND

A ground fault is a condition in an electrical system where electrical current flows to the ground outside the intended design or path. Ground faults generally result in high magnitude electrical currents which may cause personal injury, public property damage or equipment failure of the electrical system. Circuit breakers are employed in order to disconnect the electrical circuit when high magnitude electrical currents due to a ground fault are detected. High impedance ground faults, such as those that may occur when an electrical conductor is touching materials of high electrical resistance (e.g., trees, asphalt, etc.), may not generate enough current to trip a circuit breaker. Nonetheless, the current resulting from a high impedance ground fault may be enough to start fires or cause other damage.

One approach to reduce the magnitude of the current is to establish a resonant grounded power system. This approach is applied to a so called “uni-grounded” wye connected power system. In this system, all loads are connected phase-to-phase. The neutral conductor from the substation power transformer is connected to ground through an arc suppression coil, commonly known in the industry as a Peterson coil. The Peterson coil and related equipment are calibrated or tuned to be equal to the leakage capacitance of the electrical conductors supplied by the substation transformer, thereby establishing a resonant circuit at the fundamental frequency. When a single-phase ground fault occurs on this system, the leakage capacitance of the electrical conductors will discharge into the ground fault path and return to the substation transformer source through the earth. The Peterson coil inductor in the substation, which is connected between ground and the transformer neutral point, will appear as a significant impedance to the ground fault current at the fundamental frequency. This impedance in the path will limit the current flow to approximately 10% of the current which would flow in a power system which was not resonant grounded. The capacitive portion of the ground fault current is eliminated passively by the Peterson coil.

Power electronics and computer systems are installed at the same substation to measure the ground fault current. These systems use power inverters connected to a secondary or tertiary winding of the arc suppression coil to inject an equal and opposite current to eliminate the remaining 10% of the ground fault current (i.e., residual current). This active compensation component injects current to eliminate both the fundamental and harmonic components of the residual line current.

In a resonant grounded system with active compensation, the current during a ground fault is typically reduced to less than 5.0 Amperes. The passive and active compensation is occurring at the substation power transformer and impacts all feeders connected to that transformer. This has the impact of immediately limiting the current without equipment deployed on the feeders. Additionally, the electrical system can continue to be used to supply load for a limited duration (e.g., up to eight hours) until repairs are made to the faulty equipment.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 shows a diagram of one example scenario involving a power distribution system according to one or more embodiments of the present disclosure.

FIG. 2 shows a block diagram of a power distribution system according to one or more embodiments of the present disclosure.

FIG. 3 is a drawing depicting installation of a line sensor on a power line according to one or more embodiments of the present disclosure.

FIG. 4 is a flowchart illustrating an example of functionality implemented as portions of the power distribution system of FIG. 2 according to various embodiments of the present disclosure.

FIG. 5 is a flowchart illustrating an example of functionality implemented as portions of an active compensation system in the power distribution system of FIG. 2 according to various embodiments of the present disclosure.

FIGS. 6A-6B are flowcharts illustrating examples of functionality implemented as portions of a line sensor in the power distribution system of FIG. 2 according to various embodiments of the present disclosure.

FIG. 7 is a schematic block diagram that provides one example illustration of a head-end system employed in the power distribution system of FIG. 2 according to various embodiments of the present disclosure.

### DETAILED DESCRIPTION

The present disclosure relates to fault location in an active compensation resonant grounded power distribution system. Active compensation resonant grounded power distribution systems offer significant advantages in reducing forest fires, brush fires, etc. resulting from downed power lines. Moreover, when in use, the supply of power to downstream customers can continue uninterrupted, as compared to a circuit breaker that would interrupt the power to downstream customers when tripped. The power utility may receive signals indicating that the active compensation system has been activated for a given circuit. However, determining the exact location of the fault may still be time consuming, typically involving crews traveling the length of the circuit, at least until the location of the fault is discovered. The length of the circuit may be measured in tens to hundreds of miles, making the manual fault location process troublesome.

Historically, multiple devices such as conductor mounted fault indicators and line sensors are installed across a plurality of feeders to measure the presence of fault currents and indicate to the power grid operator an approximate area to find the fault location by the positive or negative indication of each device. These devices use the significant increase in fundamental frequency current to trigger and indicate a fault. The threshold which represents a significant increase is programmable in the device. In compensated systems, there is no significant surge in line current on the faulty conductor due to the cancellation of this current from the arc suppression coil and inverters. Therefore, traditional fault indicator equipment will not detect the faulted conductor. The electrical system operator will not have any information as to the location of the problem.

When the fault is being compensated by the arc suppression coil, the non-linearity of the magnetizing curve of the coil will introduce triplen harmonics (e.g., 3rd, 9th, 15th, 21st) into the current. Triplen harmonics are not created by loads except in a power system with unbalanced impedances. The active compensation is programmed to inject equal and opposite current to cancel these harmonic currents.

Various embodiments of the present disclosure employ an array of line sensors distributed along the length of the circuit in order to localize the fault when the active compensation system is activated. In various embodiments, the electronics controlling the active compensation system are modified in order to allow one or more harmonic signals (e.g., one or more triplen harmonics) to pass through the circuit affected by a ground fault uncancelled for a specific time duration or power cycle duration. The current and duration associated with these harmonic signals are selected to be minimal and not likely to cause damage and/or fires at the ground fault location.

The line sensors, which may comprise current sensors that are mounted directly on the line conductors, are configured to detect these intentionally passed harmonic signals. The line sensors may be configured to detect the harmonic signals continuously or in response to a triggering event. In some embodiments, the line sensors may capture waveform data and send the waveform data to another computer system (e.g., via a cellular data link) for analysis and determination that the harmonic signals are present. Alternatively, the line sensors may report to another computer system (e.g., via a cellular data link) that the harmonic signals are present. In this way, the system can pinpoint the location of the ground fault as between a first line sensor that does detect the harmonic signals and a second line sensor that does not detect the harmonic signals.

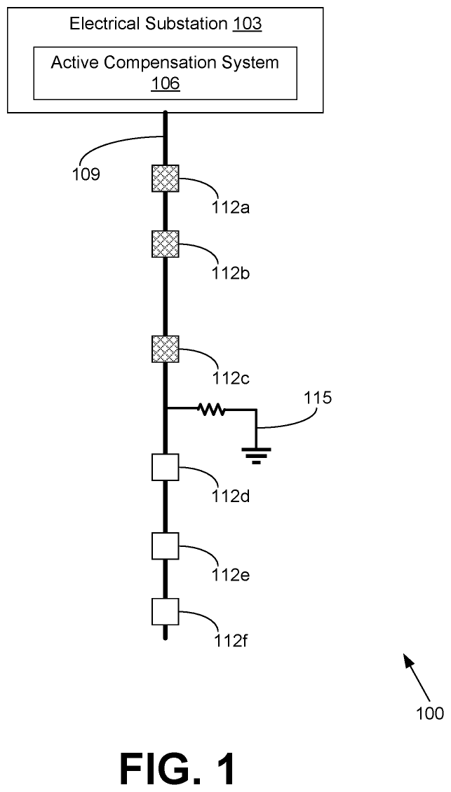

FIG. 1 shows a diagram of one example scenario involving a power distribution system 100 according to one or more embodiments. The power distribution system 100 comprises an electrical substation 103 that steps down a high voltage from a transmission line to a medium voltage (e.g., 1 kilovolt (kV) to 69 kV) for distribution. The power distribution system 100 is a resonant grounded power distribution system with an active compensation system 106 in order to cancel out ground fault currents. In accordance with the present disclosure, the active compensation system 106 may be configured not to cancel one or more harmonic currents associated with the ground fault for a programmable duration to be used for signaling.

One or more feeder power lines 109 originate at the electrical substation 103. For example, the feeder power line 109 may represent a line conductor for one phase of a multi-phase alternating current system. Disposed along the length of the feeder power line 109 may be a plurality of line sensors 112. The line sensors 112 may comprise current sensors that are attached to the line conductor via a hot stick. In this non-limiting example, six line sensors 112 are shown, line sensors 112a, 112b, 112c, 112d, 112e, and 112f, although different numbers of line sensors 112 may be employed in other examples. The line sensors 112 may be spaced at intervals along the feeder power line 109.

In this example, the feeder power line 109 experiences a ground fault 115 at a location along the feeder power line 109. For example, a tree branch may fall upon the uninsulated line conductor of the feeder power line 109 at this location, creating a high impedance ground fault that does not generate enough current to trip a circuit breaker. In the power distribution system 100, all loads are connected phase-to-phase, making it possible to detect, via an arc suppression coil, that the current of the ground fault 115 is returning via the ground.

In response to detecting the ground fault 115, the active compensation system 106 generates a signal that is at the opposite current of the ground fault current remaining after the operation of an arc suppression coil. Rather than cancelling the entirety of the ground fault current, the active compensation system 106 permits a programmable set of harmonic currents to pass through for a programmable duration (e.g., in time or in power cycles). The line sensors 112 are configured to detect this programmable set of harmonic currents. Only those line sensors 112a, 112b, and 112c that are upstream of the ground fault 115 detect the programmable set of harmonic currents, while the line sensors 112d, 112e, and 112f that are downstream of the ground fault 115 do not detect the programmable set of harmonic currents, as the harmonic currents exit via the ground fault 115. Consequently, the power utility is able to pinpoint the location of the ground fault 115 in this case as being between line sensor 112c and line sensor 112d. Restoration crews can then be dispatched by the power utility to focus on the length of the feeder power line 109 between the known location of the line sensor 112c and the known location of the line sensor 112d, rather than having to inspect the entirety of the feeder power line 109.

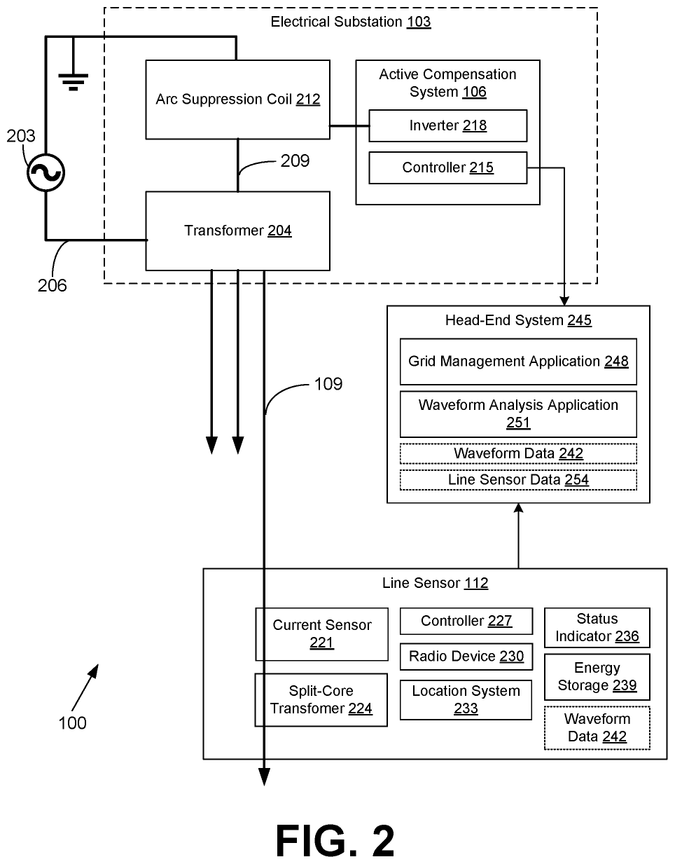

FIG. 2 shows a block diagram of a power distribution system 100 according to one or more embodiments. The power distribution system 100 includes a generator 203 coupled to a transformer 204 in an electrical substation 103 by way of a high voltage power line 206 and a neutral line 209. The high voltage power line 206 may be a multi-phase power line, e.g., employing three phases with potentially multiple line conductors per phase. The neutral line 209 is a grounded conductor. The transformer 204 steps down the high voltage to a medium voltage, which exists the electrical substation 103 as one or more feeder power lines 109. The feeder power lines 109 may be in multiple phases (e.g., three phases) with potentially multiple line conductors per phase.

An arc suppression coil 212 is an inductor that connects the neutral line 209 of the transformer 204 to ground. The inductance value may be tuned to achieve near-resonance with the total network capacitance to ground. In this condition, the connection between the neutral line 209 and ground has very high impedance at the fundamental frequency, so ground fault currents are greatly reduced, for example, from more than 1,000 Amperes to less than ten Amperes.

An active compensation system 106 is used to inject a cancellation current to reduce or nearly eliminate the residual ground fault current remaining after operation of the arc suppression coil 212. A controller 215 of the active compensation system 106 measures the ground fault current. Based upon the ground fault current, the controller 215 causes an inverter 218 connected to a secondary or tertiary winding of the arc suppression coil 212 to inject an equal and opposite current to eliminate the remaining 10% of the ground fault current (i.e., residual current).

However, rather than eliminating the residual current, the active compensation system 106 can be programmed to allow selected harmonic components of the residual current to pass along the power line 109 experiencing a ground fault for signaling purposes. These harmonic components (e.g., triplen harmonics) may be intentionally allowed to pass uncancelled for a programmable duration (e.g., in terms of number of cycles or time), after which the active compensation system 106 may be configured to cause the inverter 218 to eliminate as much of the residual current as possible.

A plurality of line sensors 112 may be installed on each of the line conductors of the feeder power lines 109. The line sensors 112 may be spaced at intervals along the line conductor. In one or more embodiments, a line sensor 112 may include, for example, a current sensor 221, a split-core transformer 224, a controller 227, a radio device 230, a location system 233, a status indicator 236, an energy storage device 239, and/or other components.

The current sensor 221 measures the current flowing through the line conductor. For example, the current sensor 221 may comprise a Hall effect sensor, a Rogowski coil, a current transformer, and/or other types of sensors. The split-core transformer 224 may fit around the line conductor, enabling the line sensor 112 to harvest energy from the magnetic field surrounding the line conductor in order to power the electronics of the line sensor 112. The split-core transformer 224 may be clamped or forced together around the line conductor after installation to minimize the gap length between split-cores of the core reluctance path, thereby improving the energy harvesting capability.

The controller 227 may correspond to an embedded computing system with a processor and a memory, an application-specific integrated circuit (ASIC), a field programmable gate array (FPGA), and/or other electronics configured to record and analyze waveform data 242, corresponding to the current waveform measurements generated by the current sensor 221. In some embodiments, the controller 227 may analyze the waveform data 242 and determine whether a programmable set of harmonic currents are present. In some embodiments, the controller 227 may upload the waveform data 242 to a head-end system 245 for analysis. In some embodiments, the controller 227 may be always analyzing the waveform data 242 as it is generated, while in other embodiments, the controller 227 may begin analyzing the waveform data 242 when a trigger event is detected. The controller 227 may also send notifications and/or activate a status indicator 236 on the line sensor 112 based upon analysis of the waveform data 242.

The radio device 230 may correspond to a wireless device such as a cellular network device (e.g., Long-Term Evolution (LTE), Fifth-Generation New Radio (5G NR)), a LoRaWAN device, a Wi-Fi device, etc. The radio device 230 may be capable of transmitting signals over relatively large distances in some embodiments. In some embodiments, the radio devices 230 in a plurality of line sensors 112 may make up a mesh network. In some cases, the radio device 230 may transmit data via the feeder power line 109.

The location system 233 may determine geographic coordinates of the line sensor 112 based upon Global Positioning System (GPS) data, or generically, Global Navigation Satellite System (GNSS) data. In some cases, the location system 233 may infer locations based upon triangulation of cellular signals, known Wi-Fi access points, and so forth.

The status indicator 236 may signal whether various faults are detected by the controller 227 and/or to signal operational status of the line sensor 112. For example, the status indicator 236 may include a light emitting diode (LED) that is activated in response to a detection of a fault. In other examples, the status indicator 236 may include an LED that is deactivated in response to a detection of a fault. In still other examples, the status indicator 236 may include an audible alarm or strobe features.

The energy storage device 239 may comprise a battery, a capacitor, etc., to store energy harvested from the line conductor by the split-core transformer 224 to assure proper operation of the line sensor 112.

The head-end system 245 may be a management system operated by the power utility. The head-end system 245 may comprise, for example, a server computer, a client computer, or any other system providing computing capability. Alternatively, the head-end system 245 may employ a plurality of computing devices that may be arranged, for example, in one or more server banks or computer banks or other arrangements. Such computing devices may be located in a single installation or may be distributed among many different geographical locations. For example, the head-end system 245 may include a plurality of computing devices that together may comprise a hosted computing resource, a grid computing resource, and/or any other distributed computing arrangement. In some cases, the head-end system 245 may correspond to an elastic computing resource where the allotted capacity of processing, network, storage, or other computing-related resources may vary over time.

Various applications and/or other functionality may be executed in the head-end system 245 according to various embodiments. Also, various data may be stored in a data store that is accessible to the head-end system 245. The data stored in the data store, for example, is associated with the operation of the various applications and/or functional entities described below.

The components executed on the head-end system 245, for example, include a grid management application 248, a waveform analysis application 251, and other applications, services, processes, systems, engines, or functionality not discussed in detail herein. The grid management application 248 may be used to monitor the status of the power distribution system 100. The grid management application 248 may also be used to activate, deactivate, or configure the operation of, various components of the power distribution system 100. For example, the grid management application 248 may receive telemetry data (e.g., from the line sensors 112 and/or the active compensation system 106 via interfaces such as Supervisory Control and Data Acquisition (SCADA) interfaces. In various scenarios, the grid management application 248 may maintain a map of the power distribution system 100 and render a predicted location of a ground fault 115 based upon data from the line sensors 112 and/or the active compensation system 106.

The waveform analysis application 251 may be used in some embodiments to perform analysis of the waveform data 242, such as to determine whether the programmable set of harmonic currents are present. It may be desirable to have the waveform analysis application 251 perform this analysis in the head-end system 245 due to limited processing and/or power capabilities of the line sensor 112. In such cases, the line sensors 112 may simply upload the waveform data 242 to the head-end system 245, and the waveform analysis application 251 performs the analysis.

The line sensor data 254 may include various data received from the line sensors 112, such as location, phase identifier, current status, whether the programmable set of harmonic currents are detected, and so forth.

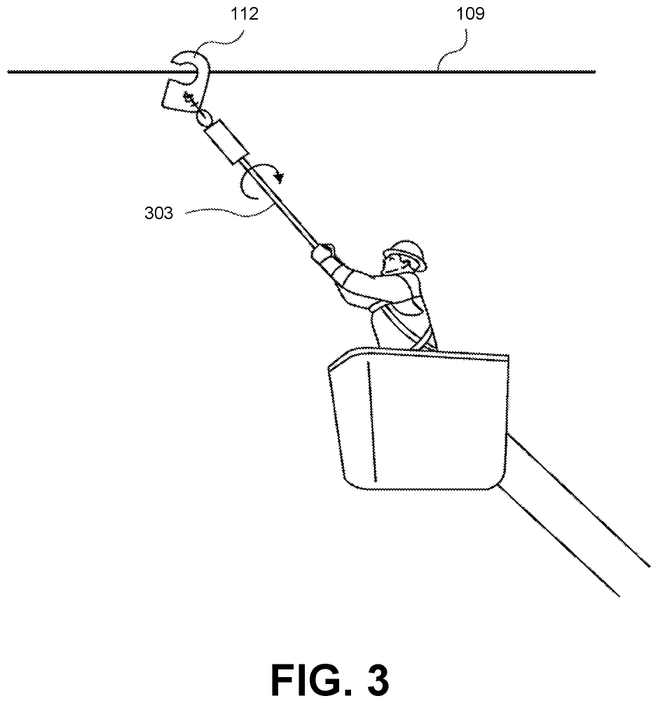

Referring next to FIG. 3, the line sensor 112 may be mounted on a feeder power line 109 using a standard “shotgun hotstick” lineman's tool 303 and handled by a single installer from a bucket truck. Installation time is an important factor for financially successful deployments of sensor arrays due to the high cost of crew time and supporting equipment. Although gloved installation is a proven process and allows close visual inspection of the conductor surface and final installation, hot stick installation is the standard required by most utility customers. In addition to a fast mechanical installation, minimized time on location also requires quick confirmation of proper core closure, system operation, and network connectivity.

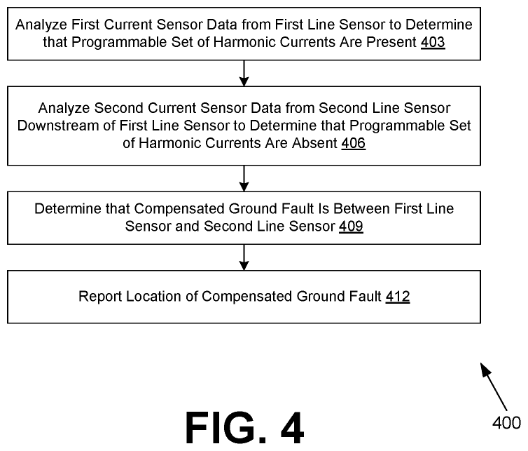

FIG. 4 is a flowchart 400 that provides one example of the operation of a portion of the power distribution system 100 according to various embodiments. It is understood that the flowchart 400 provides merely an example of the many different types of functional arrangements that may be employed to implement the operation of the portion of the power distribution system 100 as described herein.

Beginning with box 403, a first line sensor 112 and/or the head-end system 245 analyses first current sensor data from the first line sensor 112 to determine that a programmable set of harmonic currents allowed by the active compensation system 106 are present. This analysis may take place in the controller 227 of the first line sensor 112, or the first line sensor 112 may upload the waveform data 242 captured from the current sensor to the head-end system 245 for analysis by the waveform analysis application 251. For example, the head-end system 245 may send a request to the line sensors 112 monitoring the power line for capture and transmission of a line current waveform for a duration of time around the telemetry signal notification. With potentially a multitude of line sensors 112 being deployed along a feeder power line 109, it is possible that numerous ones of the line sensors 112 may capture waveform data 242 indicating that the programmable set of harmonic currents are present, up until the location of the ground fault 115.

In box 406, a second line sensor 112 and/or the head-end system 245 analyses second current sensor data from the second line sensor 112 to determine that a programmable set of harmonic currents allowed by the active compensation system 106 are absent. This analysis may take place in the controller 227 of the second line sensor 112, or the second line sensor 112 may upload the waveform data 242 captured from the current sensor to the head-end system 245 for analysis by the waveform analysis application 251. For example, the head-end system 245 may send a request to the line sensors 112 monitoring the power line for capture and transmission of a line current waveform for a duration of time around the telemetry signal notification. With potentially a multitude of line sensors 112 being deployed along a feeder power line 109, it is possible that numerous ones of the line sensors 112 may capture waveform data 242 indicating that the programmable set of harmonic currents are absent, downstream of the location of the ground fault 115. In one embodiment, the line sensors 112 that do not detect the programmable set of harmonic currents may not report, or may refrain from reporting, an indication to the head-end system 245. In such cases, the head-end system 245 may infer that the programmable set of harmonic currents are absent at a particular line sensor 112 due to a lack of a report from the particular line sensor 112.

In box 409, the grid management application 248 of the head-end system 245 determines that a compensated ground fault 115 is located between the first line sensor 112 and the second line sensor 112. In other words, the ground fault 115 is present on the length of the line conductor between a line sensor 112 that detects the harmonic currents and an immediate downstream line sensor 112 that does not.

In box 412, the grid management application 248 reports the location of the compensated ground fault 115. For example, the grid management application 248 may send one or more notifications to power utility personnel such as dispatchers. Also, the grid management application 248 may generate a map pinpointing an approximate location of the ground fault 115 using the reported locations of the line sensors 112. Thereafter, the operation of the flowchart 400 ends.

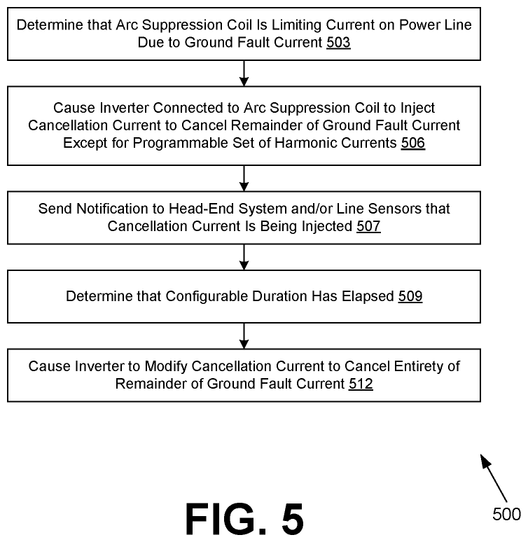

FIG. 5 is a flowchart 500 that provides one example of the operation of a portion of the active compensation system 106 according to various embodiments. It is understood that the flowchart 500 provides merely an example of the many different types of functional arrangements that may be employed to implement the operation of the portion of the active compensation system 106 as described herein.

Beginning with box 503, the active compensation system 106 determines that an arc suppression coil 212 is limiting current on the feeder power line 109 due to a ground fault current. In this operation, the arc suppression coil 212 may limit the majority of the current, even up to ninety percent. However, the arc suppression coil 212 may still let residual ground fault current through.

In box 506, the active compensation system 106 causes the inverter 218 connected to the arc suppression coil 212 to inject a cancellation current to cancel the residual or the remainder of the ground fault current. However, the cancellation current is selected such that a programmable set of harmonic currents is allowed to pass through for signaling purposes, at least for a specified or programmable duration in terms of number of cycles or time. As a non-limiting example, the duration may be 60 milliseconds.

In box 507, the active compensation system 106 may send a notification or signal to the head-end system 245 and/or the line sensors 112 indicating that the cancellation current is being injected. This may be used as a triggering event to start the capture and/or analysis of the waveform data 242 by the line sensors 112.

In box 509, the active compensation system 106 determines that a configurable duration has elapsed. In box 512, the active compensation system 106 causes the inverter 218 to modify the cancellation current to cancel the entirety (or as much as possible) of the remainder of the ground fault current. By this point, the line sensors 112 will have captured waveform data 242 that indicates the harmonic currents associated with the ground fault compensation signaling.

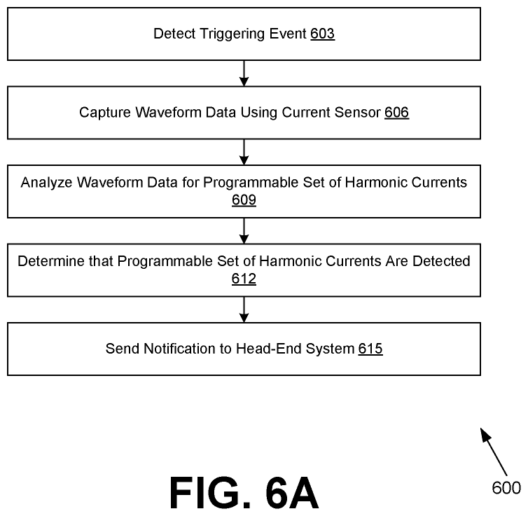

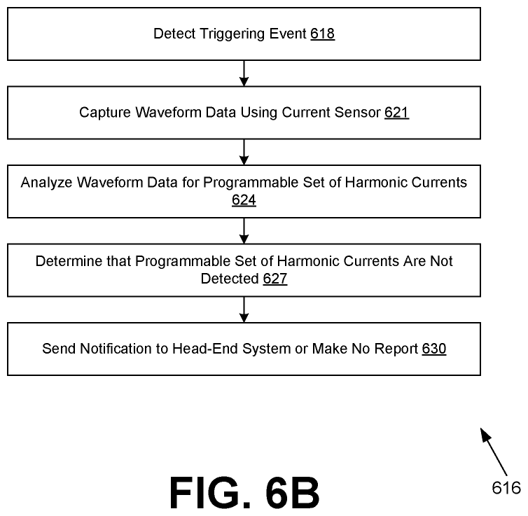

FIG. 6A is a flowchart 600 that provides one example of the operation of a portion of the line sensor 112 according to various embodiments. It is understood that the flowchart 600 provides merely an example of the many different types of functional arrangements that may be employed to implement the operation of the portion of the line sensor 112 as described herein.

Beginning with box 603, the line sensor 112 may detect a triggering event. For example, the line sensor 112 may receive a telemetry data request when the active compensation system 106 has been activated. Alternatively, the line sensor 112 may detect a drop in current on the feeder power line 109 that is commensurate with the operation of the arc suppression coil 212 (e.g., a ninety percent reduction or some other threshold). In other embodiments, the line sensor 112 may process and analyze the waveform data 242 continuously without an explicit triggering event to shift operational modes.

In box 606, the line sensor 112 captures the waveform data 242 corresponding to the current measured from the line conductor using the current sensor 221. The line sensor 112 may process the waveform data 242 on board or may send the waveform data 242 to the head-end system 245 for analysis.

In box 609, the line sensor 112 may analyze the waveform data 242 to determine whether the current readings include the programmable set of harmonic currents. By “programmable,” the combination of harmonic currents may be programmed at the manufacturer and unchangeable, or the combination of harmonic currents may be reconfigured (e.g., with a firmware update). The analysis may be performed based at least in part on a Fast Fourier Transform (FFT) and/or other approaches.

In box 612, the line sensor 112 determines that the programmable set of harmonic currents are detected in the waveform data 242. In box 615, the line sensor 112 may report or send a notification to the head-end system 245 indicating that the line sensor 112 has detected the programmable set of harmonic currents. The line sensor 112 may also activate or deactivate the status indicator 236 to indicate that the programmable set of harmonic currents has been detected.

FIG. 6B is a flowchart 616 that provides one example of the operation of a portion of the line sensor 112 according to various embodiments. It is understood that the flowchart 616 provides merely an example of the many different types of functional arrangements that may be employed to implement the operation of the portion of the line sensor 112 as described herein.

Beginning with box 618, the line sensor 112 may detect a triggering event. For example, the line sensor 112 may receive telemetry data indicating that the active compensation system 106 has been activated. The telemetry signal may request a data capture by the line sensor 112 in some embodiments. Alternatively, the line sensor 112 may detect a current reduction on the feeder power line 109 that is commensurate with the operation of the arc suppression coil 212 (e.g., a ninety percent reduction or some other threshold). In other embodiments, the line sensor 112 may process and analyze the waveform data 242 continuously without an explicit triggering event to shift operational modes.

In box 621, the line sensor 112 captures the waveform data 242 corresponding to the current measured from the line conductor using the current sensor 221. The line sensor 112 may process the waveform data 242 on board or may send the waveform data 242 to the head-end system 245 for analysis.

In box 624, the line sensor 112 may analyze the waveform data 242 to determine whether the current readings include the programmable set of harmonic currents. By “programmable,” the combination of harmonic currents may be programmed at the manufacturer and unchangeable, or the combination of harmonic currents may be reconfigured (e.g., with a firmware update). The analysis may be performed based at least in part on a Fast Fourier Transform (FFT) and/or other approaches.

In box 627, the line sensor 112 determines that the programmable set of harmonic currents are not detected in the waveform data 242. In box 630, the line sensor 112 may report or send a notification to the head-end system 245 indicating that the line sensor 112 has not detected the programmable set of harmonic currents. The line sensor 112 may also activate or deactivate the status indicator 236 to indicate that the programmable set of harmonic currents have not been detected. In some embodiments, the line sensor 112 may not report to the head-end system 245 that the that the line sensor 112 has not detected the programmable set of harmonic currents. In such a scenario, the head-end system 245 may infer that the programmable set of harmonic currents have not been detected by the line sensor 112 due to the lack of a report.

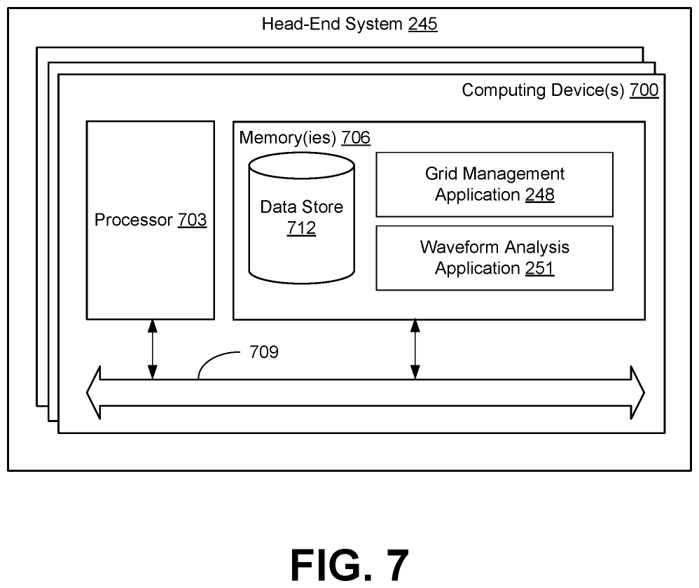

With reference to FIG. 7, shown is a schematic block diagram of the head-end system 245 according to an embodiment of the present disclosure. The head-end system 245 includes one or more computing devices 700. Each computing device 700 includes at least one processor circuit, for example, having a processor 703 and a memory 706, both of which are coupled to a local interface 709. To this end, each computing device 1000 may comprise, for example, at least one server computer or like device. The local interface 709 may comprise, for example, a data bus with an accompanying address/control bus or other bus structure as can be appreciated.

Stored in the memory 706 are both data and several components that are executable by the processor 703. In particular, stored in the memory 706 and executable by the processor 703 are the grid management application 248, the waveform analysis application 251, and potentially other applications. Also stored in the memory 706 may be a data store 712 and other data. In addition, an operating system may be stored in the memory 706 and executable by the processor 703.

It is understood that there may be other applications that are stored in the memory 706 and are executable by the processor 703 as can be appreciated. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Flash®, or other programming languages.

A number of software components are stored in the memory 706 and are executable by the processor 703. In this respect, the term “executable” means a program file that is in a form that can ultimately be run by the processor 703. Examples of executable programs may be, for example, a compiled program that can be translated into machine code in a format that can be loaded into a random access portion of the memory 706 and run by the processor 703, source code that may be expressed in proper format such as object code that is capable of being loaded into a random access portion of the memory 706 and executed by the processor 703, or source code that may be interpreted by another executable program to generate instructions in a random access portion of the memory 706 to be executed by the processor 703, etc. An executable program may be stored in any portion or component of the memory 706 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 706 is defined herein as including both volatile and nonvolatile memory and data storage components. Volatile components are those that do not retain data values upon loss of power. Nonvolatile components are those that retain data upon a loss of power. Thus, the memory 706 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 703 may represent multiple processors 703 and/or multiple processor cores and the memory 706 may represent multiple memories 706 that operate in parallel processing circuits, respectively. In such a case, the local interface 709 may be an appropriate network that facilitates communication between any two of the multiple processors 703, between any processor 703 and any of the memories 706, or between any two of the memories 706, etc. The local interface 709 may comprise additional systems designed to coordinate this communication, including, for example, performing load balancing. The processor 703 may be of electrical or of some other available construction.

Although the grid management application 248, the waveform analysis application 251, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

The flowcharts of FIGS. 4-6B show the functionality and operation of an implementation of portions of the power distribution system 100. If embodied in software, each block may represent a module, segment, or portion of code that comprises program instructions to implement the specified logical function(s). The program instructions may be embodied in the form of source code that comprises human-readable statements written in a programming language or machine code that comprises numerical instructions recognizable by a suitable execution system such as a processor 703 in a computer system or other system. The machine code may be converted from the source code, etc. If embodied in hardware, each block may represent a circuit or a number of interconnected circuits to implement the specified logical function(s).

Although the flowcharts of FIGS. 4-6B show a specific order of execution, it is understood that the order of execution may differ from that which is depicted. For example, the order of execution of two or more blocks may be scrambled relative to the order shown. Also, two or more blocks shown in succession in FIGS. 4-6B may be executed concurrently or with partial concurrence. Further, in some embodiments, one or more of the blocks shown in FIGS. 4-6B may be skipped or omitted. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present disclosure.

Also, any logic or application described herein, including the grid management application 248 and the waveform analysis application 251, that comprises software or code can be embodied in any non-transitory computer-readable medium for use by or in connection with an instruction execution system such as, for example, a processor 703 in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Further, any logic or application described herein, including the grid management application 248 and the waveform analysis application 251, may be implemented and structured in a variety of ways. For example, one or more applications described may be implemented as modules or components of a single application. Further, one or more applications described herein may be executed in shared or separate computing devices or a combination thereof. For example, a plurality of the applications described herein may execute in the same computing device 700, or in multiple computing devices 700 in the same head-end system 245.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Therefore, the following is claimed:

1. A method for determining ground fault locations in an active compensation resonant grounded power distribution system, comprising:
analyzing first current sensor data from a first line sensor mounted on a line conductor to determine that a programmable set of harmonic currents are present;
analyzing second current sensor data from a second line sensor mounted on the line conductor to determine that the programmable set of harmonic currents are absent, the second line sensor being downstream of the first line sensor on the line conductor; and
determining that a ground fault being compensated for by the active compensation resonant grounded power distribution system is present on the line conductor between the first line sensor and the second line sensor.

2. The method of claim 1, wherein the programmable set of harmonic currents are allowed to pass on the line conductor by an active compensation controller for a programmable duration.

3. The method of claim 1, further comprising detecting a triggering event before analyzing the first current sensor data and the second current sensor data.

4. The method of claim 3, wherein the triggering event comprises a telemetry signal indicating that an active compensation controller is actively injecting a compensation current to cancel a fault current.

5. The method of claim 3, wherein the triggering event comprises a drop in current measured by the first line sensor and the second line sensor meeting a threshold.

6. The method of claim 1, wherein the programmable set of harmonic currents includes a plurality of triplen harmonic currents.

7. The method of claim 6, wherein the plurality of triplen harmonic currents include a ninth harmonic current and a fifteenth harmonic current.

8. The method of claim 1, wherein the first current sensor data is analyzed by a first processor in the first line sensor, and the second current sensor data is analyzed by a second processor in the second line sensor, and the method further comprises at least one of:
reporting, by the first line sensor, to a head-end system that the programmable set of harmonic currents are present at the first line sensor;
reporting, by the second line sensor, to the head-end system that the programmable set of harmonic currents are absent at the second line sensor; or
refraining from reporting, by the second line sensor, to the head-end system when the programmable set of harmonic currents are absent at the second line sensor.

9. The method of claim 1, wherein the first current sensor data and the second current sensor data are analyzed by a head-end system, and the method further comprises:
reporting, by the first line sensor, the first current sensor data to the head-end system; and
reporting, by the second line sensor, the second current sensor data to the head-end system.

10. A method for facilitating determinations of ground fault locations in an active compensation resonant grounded power distribution system, comprising:
determining that an arc suppression coil is limiting current on a power line due to a ground fault current; and
causing an inverter connected to the arc suppression coil to inject a cancellation current on the power line to cancel a remainder of the ground fault current except for a programmable set of harmonic currents.

11. The method of claim 10, further comprising causing the inverter to modify the cancellation current to allow the programmable set of harmonic currents to pass on the power line to a ground fault location for a configurable time or number of cycles.

12. The method of claim 11, further comprising causing the inverter to modify the cancellation current to cancel an entirety of the remainder of the ground fault current after the configurable time or number of cycles.

13. The method of claim 10, further comprising sending a notification to a head-end system that the cancellation current is being injected.

14. The method of claim 10, wherein the programmable set of harmonic currents comprise a plurality of triplen harmonic currents.

15. The method of claim 10, further comprising sending a request to a plurality of line sensors monitoring the power line for capture and transmission of a line current waveform for a duration of time, the plurality of line sensors being spaced at intervals along the power line.

16. A line sensor configured to be mounted on a line conductor of a power distribution system, comprising:
a current sensor;
a radio device; and
a processor configured to at least:
analyze waveform data captured from the current sensor;
determine that the waveform data indicates that a programmable set of harmonic currents are flowing through the line conductor; and
send, using the radio device, a notification to a head-end system indicating that the programmable set of harmonic currents are detected by the line sensor.

17. The line sensor of claim 16, wherein the processor is further configured to at least analyze the waveform data in response to detecting a triggering event, the triggering event being at least one of:
a drop in current on the line conductor that meets a threshold; or
a telemetry signal from the head-end system indicating that an active compensation system is injecting a cancellation signal on the line conductor and requesting a data capture by the line sensor.

18. The line sensor of claim 16, wherein the processor is further configured to at least determine that the waveform data indicates that the programmable set of harmonic currents are flowing through the line conductor for at least a predetermined duration.

19. The line sensor of claim 16, wherein the programmable set of harmonic currents comprises a plurality of triplen harmonic currents.

20. The line sensor of claim 16, wherein the processor is further configured to at least:
determine that subsequent waveform data does not indicate that the programmable set of harmonic currents are flowing through the line conductor; and
send, using the radio device, a subsequent notification to the head-end system indicating that the programmable set of harmonic currents are not detected by the line sensor.
